(19) United States
(12) Patent Application Publication
(10) Pub. No.: US 2014/0209990 A1
(43) Pub. Date: Jul. 31, 2014

(54) SEMICONDUCTOR DEVICE AND METHOD OF MANUFACTURING THEREOF

(71) Applicant: MACRONIX INTERNATIONAL CO., LTD., Hsin-chu (TW)

(72) Inventor: Chi-Pin Lu, Hsinchu County (TW)

(73) Assignee: MACRONIX INTERNATIONAL CO., LTD., Hsin-chu (TW)

(21) Appl. No.: 13/749,828

(22) Filed: Jan. 25, 2013

(51) Int. Cl. H01L 29/792; H01L 21/02; H01L 23/48

(52) U.S. Cl. CPC H01L 29/792; H01L 23/48; H01L 21/02697
USPC 257/315; 257/773; 438/585

(57) ABSTRACT

A memory device is provided having an improved gate coupling ratio, substantial suppression of p-type dopant segregation, and reduction in inter-poly dielectric current leakage. The memory device may be substantially free of any void spaces in a second conductive layer. Methods of manufacturing such a memory device are also provided.

### TECHNOLOGICAL FIELD

The present invention generally relates to a structure of a semiconductor device and a method of forming the semiconductor device. In particular, the present invention relates to an improved memory device and a method for manufacturing such a memory device.

### BACKGROUND

The conventional floating gate memory cell may comprise a substrate, a silicon oxide layer, a floating gate, and a shallow trench isolation (STI) array comprising trenches. The conventional floating gate memory cell may also comprise an isolation fill material that is substantially disposed in the trenches. An oxide/nitride/oxide (ONO) layer may be disposed along the floating gate and the fill material. The conventional floating gate memory cell may additionally comprise a control gate.

Conventional floating gate memory cells suffer from inter-poly dielectric (IPD) leakage current resulting in a small program window, poor endurance, and poor data retention in the flash memory device. There remains a need in the art for alternative memory device structures that resolve the problem of IPD current leakage especially as the size of such devices become further reduced.

Additionally, conventional floating gate memory cells are subject to boron segregation resulting in a reduced concentration of p-type dopant in the vicinity of the surface of the silicon substrate. As the memory device is being fabricated, the boron in the substrate has a tendency to segregate from the substrate. There remains a need in the art for alternative memory device structures and/or alternative methods of fabricating such structures to limit the extent of boron segregation that may otherwise occur.

Furthermore, due to the close proximity of the floating gates in a conventional floating gate memory cell, conventional processing techniques have a tendency to leave void spaces when the control gate layer is deposited across the conventional floating gate memory cell. These void spaces may result in random reliability issues that can compromise the operability of the conventional floating gate memory cell. There remains a need in the art for memory device structures and/or methods of fabricating such structures to decrease or even substantially eliminate the formation of void spaces in the control gate.

“Gate coupling ratio” is defined as the ratio of a voltage that is induced on the floating gate relative to the amount of voltage applied to the control gate. Under the most ideal circumstances, perfect coupling results in a ratio of 100%. However, conventional floating gate memory cells do not have a gate coupling ratio of 100%. There remains a need in the art for semiconductor device structures and/or methods of fabricating such structures to improve the gate coupling ratio, but without compromising the reliability and/or operability of the device.

### BRIEF SUMMARY OF EXEMPLARY EMBODIMENTS

Embodiments of the present invention are therefore provided that may provide for a memory device having improved control gate fill-in, improved gate coupling ratio, and/or suppression of shallow trench isolation (STI) dopant segregation.

An aspect of the invention provides a semiconductor device comprising a substrate, a first dielectric layer disposed on the substrate, a first conductive layer disposed on the first dielectric layer, a film that covers a bottom portion of the first conductive layer, a trench disposed in the substrate, a liner layer substantially disposed along a sidewall of the trench, and a fill material disposed in the trench that substantially surrounds the film.

In an embodiment of the invention, a top portion of the film may be substantially the same level as a top portion of the fill material. In certain embodiments of the invention, a width of the first conductive layer may be smaller than a width of the substrate.

In an embodiment of the invention, the semiconductor device comprises a second dielectric layer that is conformally applied to a top portion of the first conductive layer and the fill material. In certain embodiments of the invention, the second dielectric layer may be an oxide/nitride/oxide layer. The semiconductor device may additionally comprise a second conductive layer.

According to an embodiment of the invention, the bottom of the film is substantially aligned with and coplanar to the first dielectric layer. In certain embodiments of the invention, the film has thickness anywhere in a range of from about 80 Å to about 100 Å. In certain embodiments of the invention, a cross-section of a top portion of the first conductive layer is substantially rounded in shape.

According to certain embodiments of the invention, the first conductive layer is configured to be a floating gate layer. In certain embodiments of the invention, the liner layer may comprise a silicon nitride. In yet other embodiments of the invention, the first dielectric layer may be a silicon oxide layer.

According to certain embodiments of the invention, a semiconductor comprising a first conductive layer having a top portion substantially rounded in shape; a film that covers a bottom portion of the first conductive layer; and a fill material that substantially surrounds the film is provided.

An aspect of the invention also provides a method of fabricating a memory device. The method of fabricating a memory device comprises the steps of providing a substrate, a first dielectric layer, and a first conductive layer; patterning the first dielectric layer and the first conductive layer; trimming a sidewall of the first conductive layer to form a film; forming a trench in the substrate; filling the trench with a fill material; and rounding a top portion of the first conductive layer.

The method of fabricating a memory device may additionally comprise the steps of forming a second dielectric layer on the first conductive layer; and forming a second conductive layer on the second dielectric layer.

In certain embodiments of the invention, a top portion of the film is at substantially the same level as a top portion of the fill material. According to certain embodiments of the invention, a width of the first conductive layer is smaller than a width of the substrate.

In an embodiment of the invention, the film may be formed by any one or both of a plasma oxidation process and a radical oxidation process operating at a temperature in a range of from about 500° C. to about 600° C.

In an embodiment of the invention, the method of fabricating a memory device may comprise the step of depositing a sidewall liner substantially along a sidewall of the trench. In certain embodiments of the invention, the sidewall liner is deposited using a selective nitridation process wherein a silicon nitride is substantially disposed along the sidewall but the film remains substantially free of any silicon nitride. In certain embodiments of the invention, the selective nitridation process may be a plasma nitridation processing having a bias in a range of from about 200 W to about 400 W and a pressure in a range of from about 1 torr to about 2 torr. In certain embodiments of the invention, the plasma nitridation process may operate at a temperature anywhere in a range of from about 400° C. to about 500° C.

The method of fabricating a memory device may additionally comprise the step of etching back the fill material to provide an exposed portion of the first conductive layer. In certain embodiments of the invention, a height of the exposed portion of the first conductive layer is at least about 200 Å. In certain embodiments of the invention, the exposed portion resembles a geometric shape having a top part and a bottom part, the top part narrower than the bottom part. In certain embodiments of the invention, the geometric shape of the top portion of the first conductive layer is approximately trapezoidal in shape.

A method of fabricating a semiconductor, according to an embodiment of the invention, comprises the steps of providing a semiconductor comprising a first conductive layer, and a hard mask; etching the hard mask to form a hard mask pattern; further etching the first conductive layer to define a trench surrounding the first conductive layer; trimming the first conductive layer and the hard mask with a film; filling the trench with a fill material; etching back the fill material to provide an exposed portion of the first conductive layer and to remove the hard mask; further etching the first conductive layer such that a cross-section of the exposed portion resembles a geometric shape having a top part that is more narrow than a bottom part; and oxidizing the first conductive layer such that a top portion of the first conductive layer becomes substantially rounded.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates a cross-section of a memory device according to an embodiment of the invention;

FIG. 2 illustrates a cross-section of a semiconductor having a substrate, a first dielectric layer, a first conductive layer, and a hard mask layer according to an embodiment of the invention;

FIG. 3 illustrates a cross-section of a semiconductor after the hard mask has been etched to form a hard mask patter according to an embodiment of the invention;

FIG. 4 illustrates a cross-section of a semiconductor after the first conductive layer has been further etched according to an embodiment of the invention;

FIG. 5 illustrates a cross-section of a semiconductor device after the first conductive layer and the hard mask has been trimmed with a second dielectric film according to an embodiment of the invention;

FIG. 6 illustrates a cross-section of a semiconductor after a STI array has been etched into the substrate according to an embodiment of the invention;

FIG. 7 illustrates a cross-section of a semiconductor after a third dielectric layer has been applied to a sidewall of any trench of the STI array according to an embodiment of the invention;

FIG. 8 illustrates a cross-section of a semiconductor after the trenches of the SDI array have been filled using a fill material according to an embodiment of the invention;

FIG. 9 illustrates a cross-section of a semiconductor after the fill material has been etched back and the hard mask removed according to an embodiment of the invention;

FIG. 10 illustrates a cross-section of a semiconductor after the first conductive layer has been further etched back to form a geometric shape in a top portion of the first conductive layer according to an embodiment of the invention;

FIG. 11 illustrates a cross-section of a semiconductor as a second dielectric layer is applied to the top portion of the first conductive layer according to an embodiment of the invention;

FIG. 12 illustrates a cross-section of a semiconductor after the fill material has been further etched according to an embodiment of the invention;

FIG. 13 illustrates a cross-section of a semiconductor after depositing a second dielectric layer according to an embodiment of the invention;

FIG. 14 is a flowchart showing the steps of fabricating a memory device according to an embodiment of the invention; and

FIG. 15 is a flowchart showing the steps of fabricating a memory device according to another embodiment of the invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a memory device” includes a plurality of such memory devices.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “shallow trench” is intended to mean the structure employed in shallow trench isolation (“STI”) of a semiconductor. Generally, a shallow trench is defined by sidewalls and a bottom. However, in some shallow trenches, depending on the aspect ratio and depth of the trench, the formation of a distinct bottom portion, in some cases, may not be clearly distinguishable from the convergence of the sidewalls at the bottom portion of the trench.

The inventors have conceived of a memory device having improved control gate fill-in, an improved gate coupling ratio, and/or suppression of STI dopant segregation. In certain embodiments of the invention, processes and methods provide an improved memory device of the invention while having a substantial reduction in void.

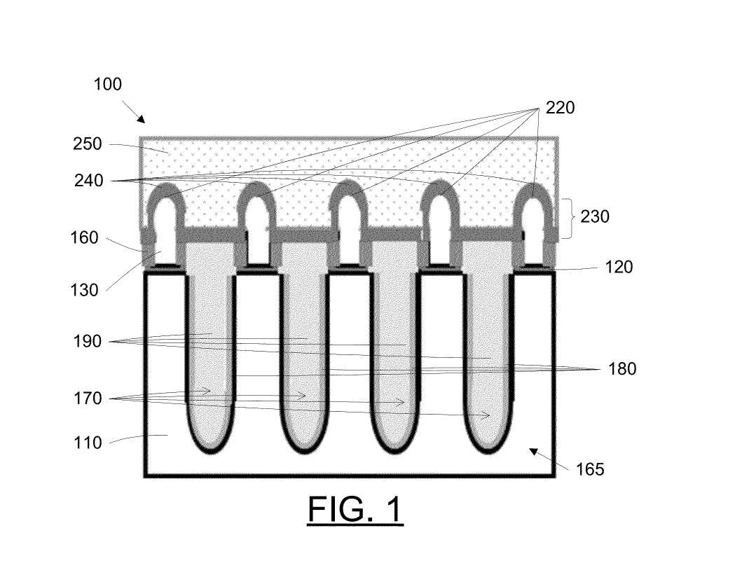

FIG. 1 illustrates a cross-section of a memory device according to an exemplary embodiment of the invention. The memory device 100 of the invention comprises a substrate 110 upon which is disposed a first dielectric layer 120 and a first conductive layer 130. In an embodiment of the invention, the first dielectric layer 120 is a silicon oxide layer. The first conductive layer 130 may be a floating gate in certain embodiments of the invention.

The first conductive layer 130 is surrounded, in part, by a film 160. As further shown in the illustrative embodiment of FIG. 1, the bottom of the film 160 may be configured to be substantially aligned with and coplanar to the first dielectric layer 120. According to an embodiment of the invention, the film 160 may comprise a silicon oxide.

A plurality of STIs 165 have been formed into the substrate 110 of the memory device 100 and a sidewall liner 180 is deposited along a sidewall of any trench 170 of the STIs 165. Each trench 170 is filled with a fill material 190. In an embodiment of the invention, the fill material 190 may comprise an oxide material.

In an embodiment of the invention, the first conductive layer 130 may be a height 230 that extends above the fill material 190. The illustrative embodiment of FIG. 1 shows a memory device wherein a top portion 220 of the first conductive layer 130 is substantially rounded. Further pursuant to this embodiment, a second dielectric layer 240 has been applied to the surface of the first conductive layer 130 that extends above the fill material by a depth 230. According to an embodiment of the invention, the second dielectric layer 240 is an oxide-nitride-oxide (ONO) layer.

The memory device may additionally comprise a second conductive layer 250. According to an embodiment of the invention, the second conductive layer 250 may be a control gate.

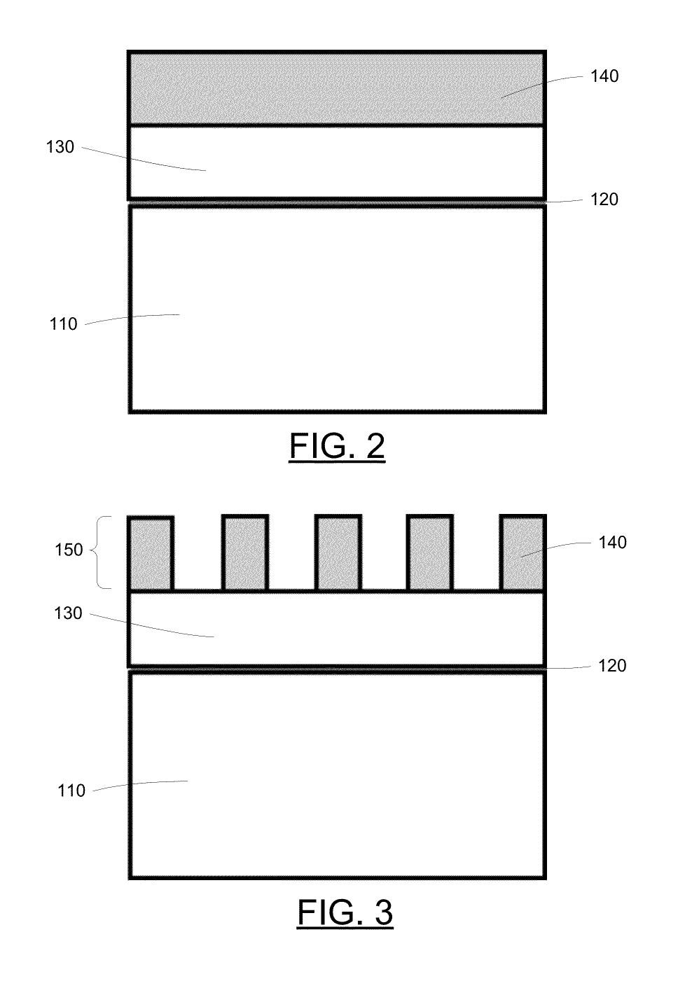

FIGS. 2-13, whose explanations follow, are directed to manufacturing a memory device according to an exemplary embodiment of the invention. FIG. 2 shows providing a semiconductor having a substrate 110 upon which is formed a first dielectric layer 120. A first conductive layer 130 is disposed on the first dielectric layer 120, and a hard mask 140 is deposited on the first conductive layer 130 according to an embodiment of the invention.

In one embodiment of the invention, the first dielectric layer 120 is a silicon oxide layer. In certain embodiments of the invention, the first conductive layer 130 is a polysilicon layer. In certain embodiments of the invention, the hard mask 140 comprises a silicon nitride (Si₃N₄).

FIG. 3 illustrates a cross-section of a semiconductor in an embodiment of the invention after the hard mask layer 140 has been etched to form a hard mask pattern 150.

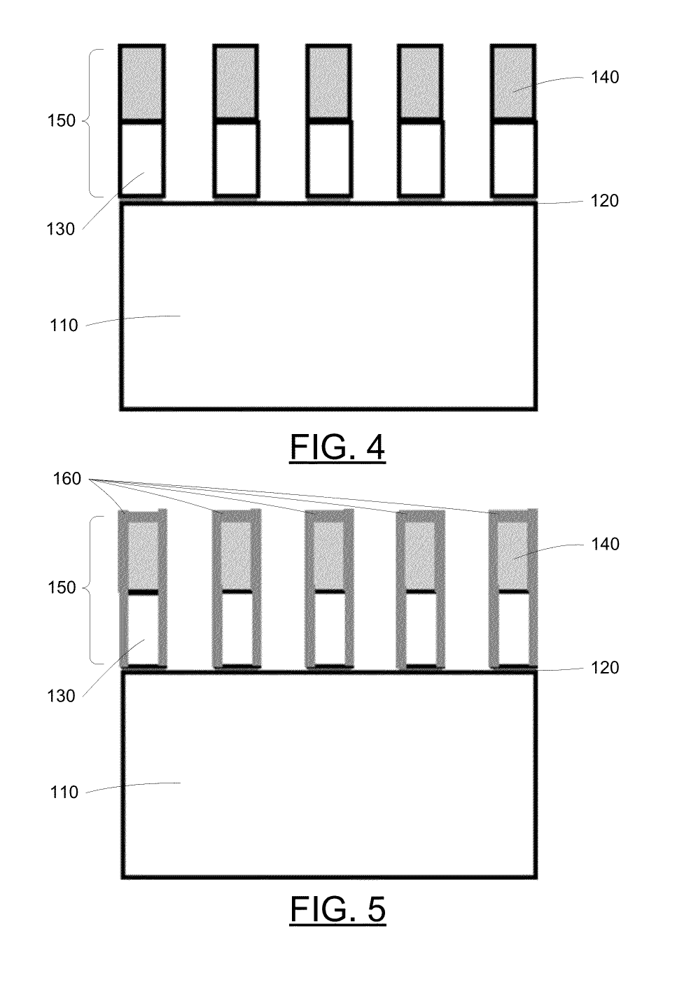

FIG. 4 illustrates a cross-section of a semiconductor after the first conductive layer 130 has additionally been etched according to the pattern 150 in an embodiment of the invention. In an embodiment of the invention, the first dielectric layer 120 may also be removed in this subsequent etching process according to the pattern 150.

FIG. 5 illustrates a cross-section of a semiconductor after the first conductive layer 130 and the hard mask 140 has been trimmed and a film 160 is formed according to an embodiment of the invention. According to an embodiment of the invention, the film 160 may comprise a silicon dioxide. In an embodiment of the invention, the film 160 may be applied to the outer surfaces of the first conductive layer 130 and the hard mask 140 using a low temperature deposition process. For example, the low temperature deposition process may apply a silicon dioxide liner layer.

In another embodiment of the invention, the film 160 may be formed along the outer surfaces of the first conductive layer 130 and the hard mask 140 using a low temperature oxidation process. In certain embodiments of the invention, the low temperature oxidation process operates at a temperature in a range of from about 500° C. to about 600° C. The low temperature oxidation process, in certain embodiments of the invention, may be a plasma oxidation process and/or a radical oxidation process. In certain embodiments of the invention, a thickness of the film 160 may be from about 80 Å to about 100 Å.

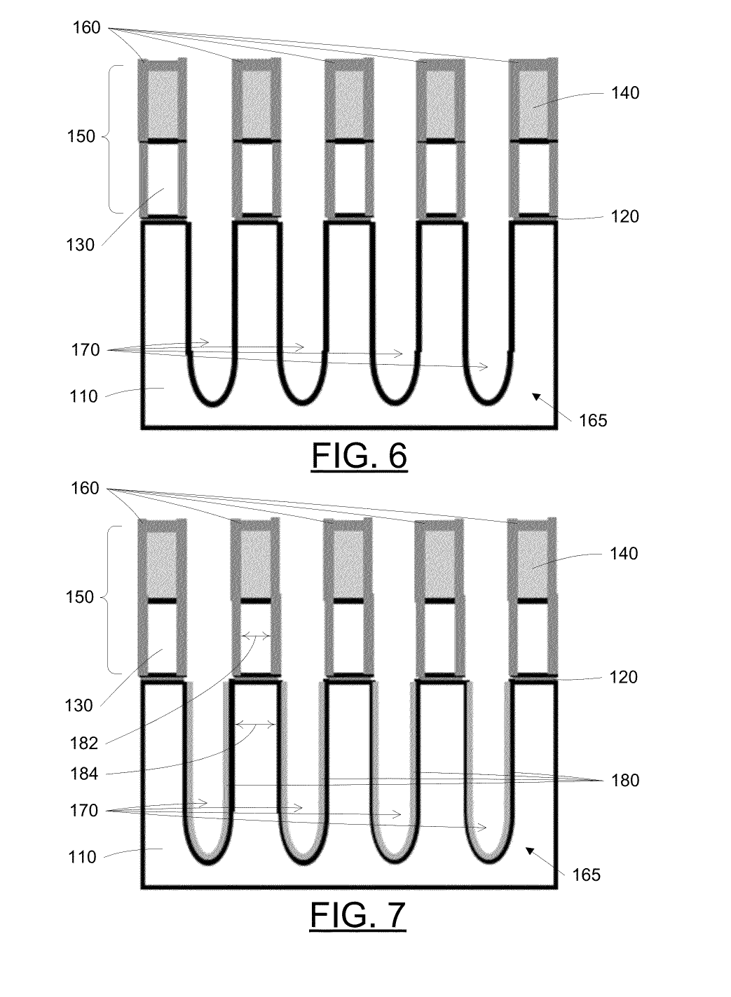

FIG. 6 illustrates a cross-section of the semiconductor after STIs 165 have been etched into the substrate 110 according to an embodiment of the invention. Any process known in the art may be used to form the STIs 165 in the substrate 110. However, processes that provide a smooth finish to the trenches 170 of the STIs 165 may be preferred embodiments of the invention.

FIG. 7 illustrates a cross-section of a semiconductor of the invention after a sidewall liner 180 has been applied to a sidewall of any trench 170 of the STIs 165. According to an embodiment of the invention, the sidewall liner 180 may comprise a silicon nitride and may be deposited using a nitridation process.

Without intending to be bound by theory, the sidewall liner 180 of the invention may reduce the extent of boron segregation from the substrate 110 into the fill material 190, as further discussed herein, as the semiconductor continues to undergo various step in fabricating the device. In an embodiment of the invention, the sidewall liner 180 may suppress the extent of boron segregation from the substrate into the STI fill material 190 by at least about 10%, at least about 20%, and at least about 30% in comparison to the extent of boron segregation that would otherwise occur if the sidewall liner 180 of the invention was not applied. In certain embodiments of the invention, the sidewall liner 180 suppresses the extent of segregation of boron from the substrate into the STI fill material 190 by at least about 40% in comparison to the extent of boron segregation that would otherwise occur if the sidewall liner 180 of the invention was not applied.

According to an embodiment of the invention, the first conductive layer 130 is defined by a width D1 182 and the substrate 110 is defined by a width D2 184. In an embodiment of the invention, the width D1 182 may be about the same as the width D2 184. In an embodiment of the invention, the width D1 182 may be smaller than the width D2 184, for example, the width D1 182 may be at least about 5% smaller than the width D2 184, the width D1 182 may be at least about 10% smaller than the width D2 184, the width D1 182 may be at least about 15% smaller than the width D2 184, the width D1 182 may be at least about 20% smaller than the width D2 184, or the width D1 182 may be at least about 25% smaller than the width D2 184. In an embodiment of the invention, the width D1 182 may be substantially smaller than the width D2 184.

In certain embodiments of the invention, the nitridation process is a selective nitridation whereby the silicon nitride is substantially disposed along the sidewall of the trench, but the film 160 surrounding the first conductive layer 130 and the hard mask 140 is substantially free of any silicon nitride. For example, the film 160 may comprise an oxide, and the silicon nitride may preferably not be deposited on the film 160 under the conditions of the nitridation process. By way of example, but without intending to be bound by theory, the conditions of the nitridation process are sufficient to break silicon bonds to allow a silicon nitride layer to be deposited along the sidewalls but are not sufficient to break the silicon and oxide bonds thus preventing formation of a silicon nitride layer at the film 160.

In an embodiment of the invention, the nitridation process may be a high pressure nitridation process. In certain embodiments of the invention, the nitridation process operates at a pressure in a range of from about 1 torr to about 2 torr. In certain embodiments of the invention, the nitridation process operates at a temperature in a range of from about 400° C. to about 500° C.

In an embodiment of the invention, the nitridation process may be a plasma nitridation. In certain embodiments of the invention, the plasma nitridation may operate at a temperature in a range of from about 400° C. to about 500° C. In certain embodiments of the invention, the plasma nitridation process operates at about 1,500 watts. In certain embodiments of the invention, the nitridation process is operated with a bias. In certain embodiments of the invention, the bias may be from about 200 W to about 400 W. In an embodiment of the invention, the gas used in the nitridation process comprises nitrogen and an inert gas. In certain embodiments of the invention, the inert gas may comprise argon.

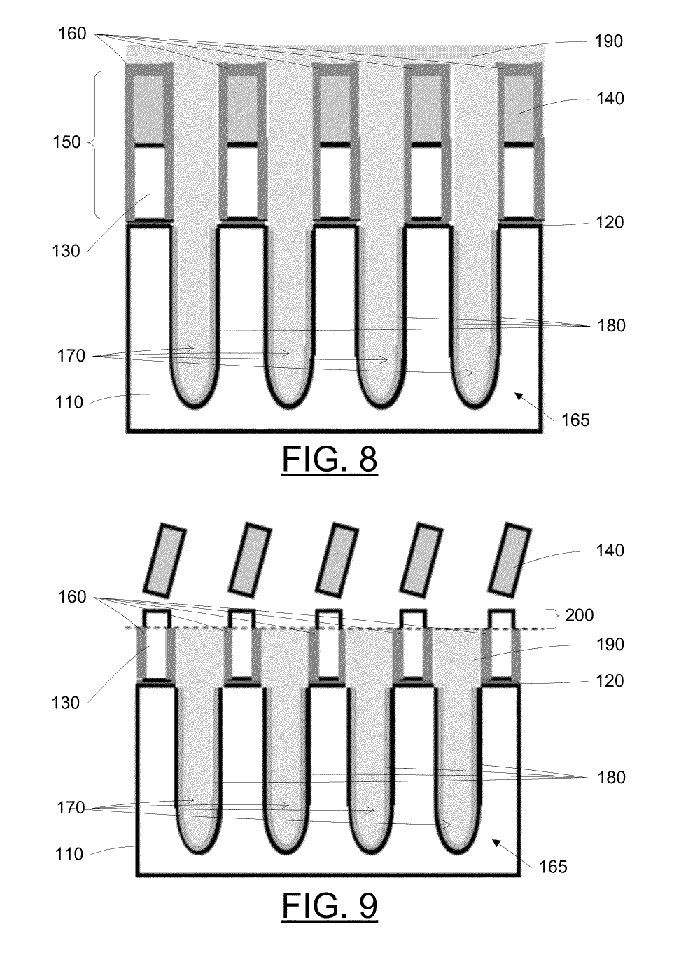

FIG. 8 illustrates a cross-section of a semiconductor of the invention after the STI array 170 has been filled with a fill material 190. For example, the fill material 190 may comprise an oxide that is filled using any one or more of a high density plasma (HDP) process and a spin on dielectric process (SOD).

FIG. 9 illustrates a cross-section of a semiconductor after the fill material 190 and the hard mask 140 has been etched back according to an embodiment of the invention. In an embodiment of the invention, the enough fill material 190 will be removed such that a portion of the first conductive layer 130 is exposed and is not covered by the fill material 190. In an embodiment of the invention, a top portion of the film 160 may be at substantially the same level as a top portion of the fill material 190. In certain embodiments of the invention, a depth 200 of the exposed portion of the first conductive layer 130 not covered by the fill material 190 is at least about 200 Å. In certain embodiments of the invention, the depth 200 of the exposed portion of the first conductive layer 130 not covered by the fill material 190 is about 200 Å.

Any of a wet etch process, a dry etch process, or a combination thereof may be used to etch back the fill material 190 and to remove the hard mask 140. In certain embodiments of the invention, a hot phosphoric acid (H₃PO₄) is used to etch back the fill material 190 and remove hard mask 160.

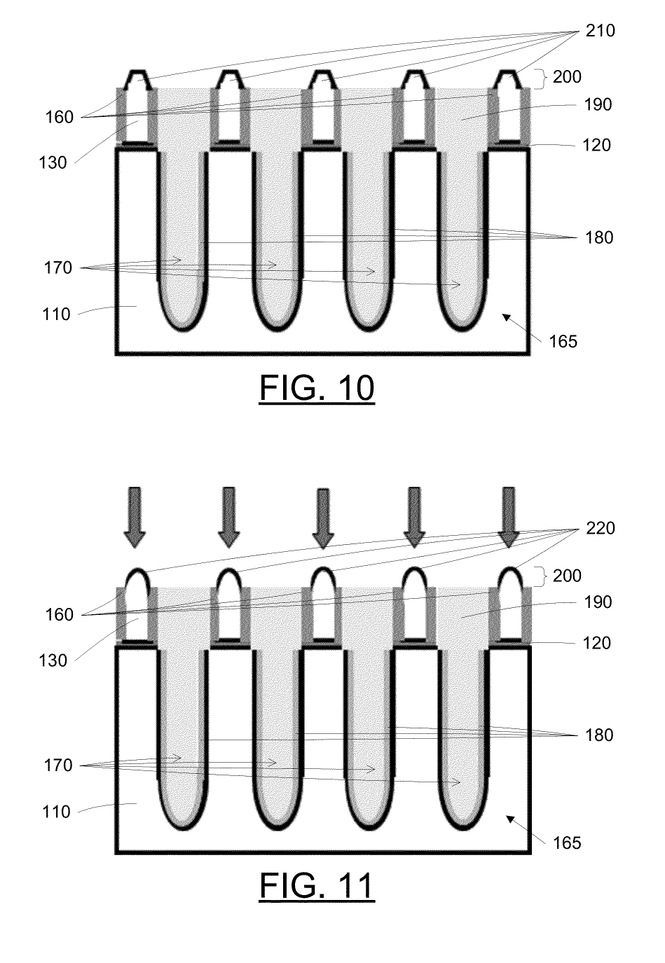

FIG. 10 illustrates a cross-section of a semiconductor of the invention where the first conductive layer 130 has been further etched to form a geometric shape 210 such that a lower portion towards the bottom of the exposed portion of the conductive layer 130 is larger than an upper portion towards a top of the conductive layer 130. In an embodiment of the invention, the geometric shape may be approximately trapezoidal in cross-section. In an embodiment of the invention, the geometric shape may be substantially trapezoidal in cross-section. According to an embodiment of the invention, the first conductive layer 130 may be further etched using a wet etch process to form the geometric shape 210. In certain embodiments of the invention, the first conductive layer may be further etched using a hot phosphoric acid to form the geometric shape 210.

FIG. 11 illustrates a cross-section of a semiconductor as a top portion 220 of the first conductive layer 130, according to an embodiment of the invention, undergoes oxidation. In an embodiment of the invention, the top portion 220 of the first conductive layer 130 may become substantially rounded.

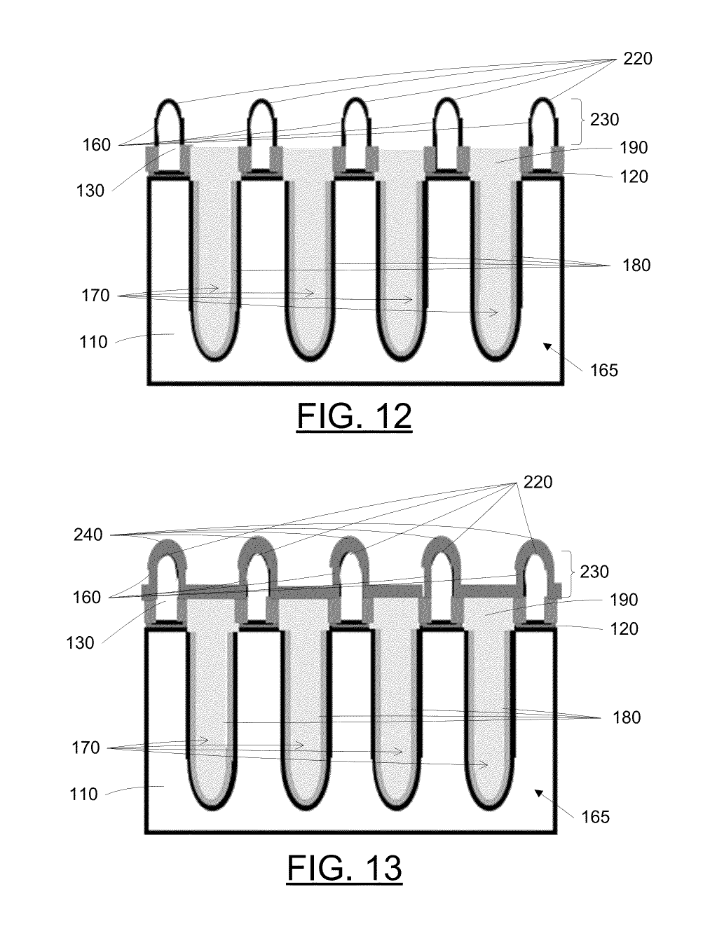

FIG. 12, according to an embodiment of the invention, shows a cross-section of a semiconductor after the fill material 190 has been further etched to expose a depth 230 of the first conductive layer 130 that is not covered by the fill material 190. In certain embodiments of the invention, the depth 230 of the exposed portion of the first conductive layer 130 not covered by the fill material 190 is at least about 300 Å.

FIG. 13 illustrates a cross-section of a semiconductor, according to an embodiment of the invention, after a second dielectric layer 240 has been conformably applied to an outer surface of the first conductive layer 130 not covered by the fill material 190 and the fill material 190 itself. According to an embodiment of the invention, the second dielectric layer 240 may be an oxide-nitride-oxide layer.

A second conductive layer may then be applied to the semiconductor. FIG. 1 shows a finished memory device, according to an embodiment of the invention, having a second conductive layer 250. Without intending to be bound by theory, the film 160 surrounding only a bottom portion of the first conductive layer 130 allows the second conductive layer 250 to be applied but with a substantial reduction in the size of void fractions that may form in the second conductive layer 250 due to, without intending to be bound by the theory, the smaller width and rounded top portion of the floating gate. In certain embodiments of the invention, without further intending to be bound by theory, the film 160 surrounding only a bottom portion of the first conductive layer 130 allows the second conductive layer 250 to be applied but substantially without the formation of any void fractions in the second conductive layer 250.

Without intending to be bound by theory, the resulting rounded configuration of the top portion 220 of the first conductive layer 130 results in an improvement of the gate coupling ratio. According to certain embodiments of the invention, the memory device of the invention results in at least about a 10% improvement in the gate coupling ration. In certain other embodiments of the invention, the memory device of the invention results in at least about a 20% improvement in the gate coupling ration. In yet other embodiments of the invention, the memory device of the invention may result in about a 10% to about a 20% improvement in the gate coupling ratio.

Without intending to be bound by theory, the inventive memory device will allow for an increase in electric field through the inter-poly dielectrics, suppression in p-type dopant (e.g., boron) segregation, improved gate coupling ratio, and a substantial reduction if not elimination altogether of void spaces that become formed in the second conductive layer. Without intending to be limiting, examples of devices where the inventive memory structure may be used include NAND floating gate memory devices, and any NOR structure and NAND structure where a similar STI array is used.

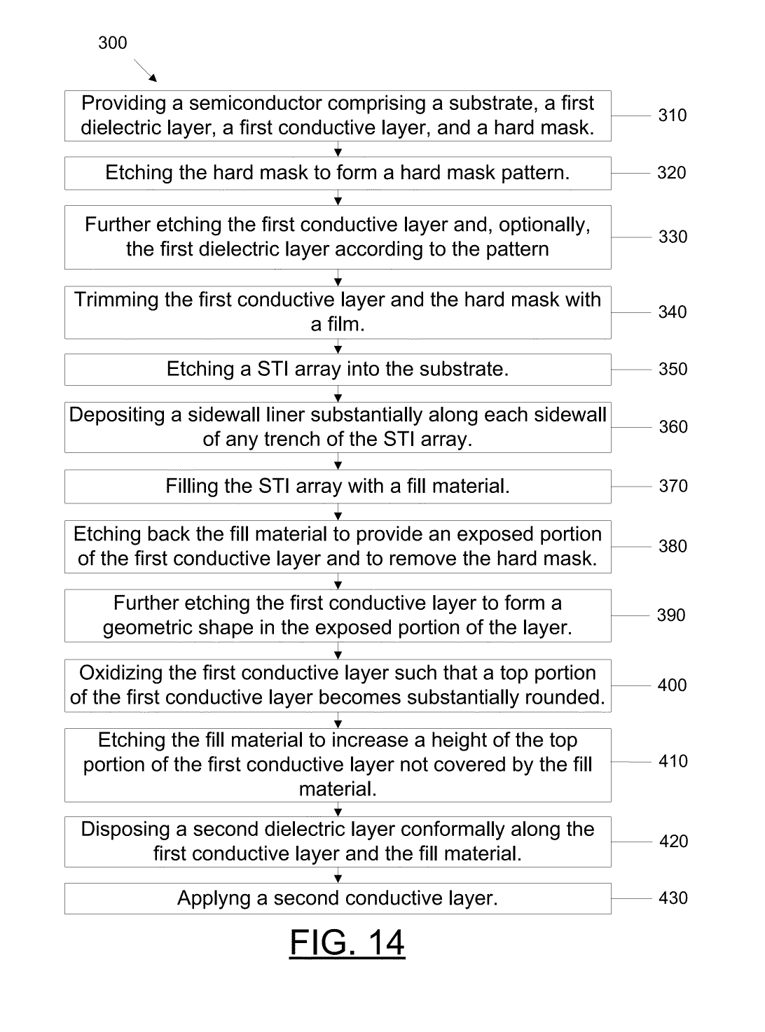

FIG. 14 is a flowchart showing the steps of fabricating a memory device according to an embodiment of the invention. The method of fabricating a memory structure 300 comprises a step of providing a semiconductor having a substrate, a first dielectric layer, a first conductive layer, and a hard mask 310. The method of fabricating a semiconductor memory device 300 additionally may comprise a step of etching the hard mask to form a hard mask pattern 320, and further etching the first conductive layer and, optionally, the first dielectric layer according to the hard mask pattern 330. Any method known in the art may be used to etch the hard mask, the first conductive layer, and the first dielectric layer.

Following the step of further etching the first conductive layer 320, the method of fabricating a memory device 300 may comprise a step of trimming the first conductive layer and the hard mask with a film 340. Following these steps, the profile of the resulting semiconductor is similar to that defined in FIG. 5.

The method of fabricating a memory device 300 further comprises the step of etching a STI array into the substrate 350 resulting in a semiconductor structure similar to that shown in FIG. 6. The semiconductor having these better defined trenches may then be subjected to additional steps. For example, the method of fabricating a memory device 300 may comprise the step of depositing a sidewall liner substantially along each sidewall of any trench of the STI array 360 and filling the STI array with a fill material 370 resulting in a semiconductor structure similar to that shown in FIG. 8 according to certain embodiments of the invention.

Any conventional technique known in the art may be used to fill the STI array with a fill material. Any excess fill material applied to the semiconductor structure may be removed from the gate structure. For example, a chemical mechanical planarization process is an exemplary process the may be used to remove the excess filling material from the trench. Topologically selective slurry and/or an abrasive trapped pad or abrasive mounted pad may be used in the removal operation. However, any process known in the art for the removal of excess filling material may be used to remove the excess filling material from the trench.

Indeed, a step of the method for fabricating a memory device 300 may include etching back the fill material to provide an exposed portion of the first conductive layer and to remove the hard mask 380. The resulting semiconductor structure following this step is shown in FIG. 9 in an illustrative exemplary embodiment. The semiconductor is then subjected to further etching the first conductive layer to form a geometric shape in the exposed potion of the first conductive layer 390. According to certain embodiments of the invention, the geometric shape may resemble a trapezoidal shape similar to the shown in FIG. 10, for example.

The semiconductor is then subjected to the step of oxidizing a top portion of the first conductive layer such that the top portion of the first conductive layer becomes substantially rounded 400 similar to that shown in FIG. 11 according to an exemplary embodiment of the invention. The semiconductor is then subjected to further etching the fill material to increase a height of the top portion of the first conductive layer not covered by the fill material 410. The semiconductor structure of FIG. 12 is represented of the resulting structure following this step.

The method of fabricating a memory device 300 may then comprise the step of disposing a second dielectric layer conformally along the first conductive layer and the fill material 420 resulting in the exemplary embodiment of FIG. 13. Finally, a second conductive layer may be applied 430 to produce an exemplary memory device of the invention illustrated FIG. 1.

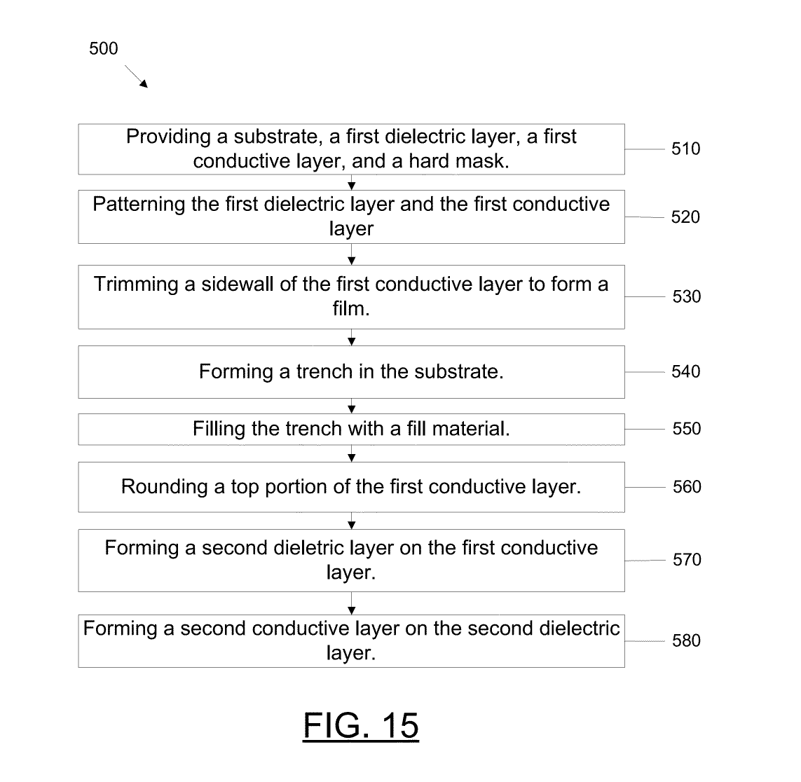

FIG. 15 is a flowchart showing the steps of fabricating a memory device according to another embodiment of the invention. The method of fabricating a memory device 500 may comprise the steps of providing a substrate, a first dielectric layer, and a first conductive layer 510; patterning the first dielectric layer and the first conductive layer 520; trimming a sidewall of the first conductive layer to form a film 530; forming a trench in the substrate 540; filling the trench with a fill material 550; rounding a top portion of the first conductive layer 560; forming a second dielectric layer on the first conductive layer 570; and forming a second conductive layer on the second dielectric layer 580.

In certain embodiments of the invention, the film may be formed by at least one of a plasma oxidation process and a radical oxidation process operating at a temperature in a range of from about 500° C. to about 600° C.

The method of fabricating a memory device may additionally comprise the step of depositing a sidewall liner substantially along a sidewall of the trench. For example, as disclosed herein, depositing the sidewall liner may comprise a selective nitridation process that forms a silicon nitride substantially along the sidewall but allowing the film to remain substantially free of any silicon nitride. In certain embodiments of the invention, the selective nitridation process may operate at a pressure in a range of from about 1 torr to about 2 torn In certain embodiments of the invention, the nitridation process may have a bias in a range of from about 200 W to about 400 W.

An aspect of the invention provides a memory device fabricated according to the processes or methods for fabricating a memory device of the invention. In certain other embodiments of the invention, a semiconductor device may be fabricated using any methods as described herein.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A semiconductor device comprising:
a substrate;
a first dielectric layer disposed on the substrate;
a first conductive layer disposed on the first dielectric layer;
a film that covers a bottom portion of the first conductive layer;
a trench defined in the substrate;
a liner layer substantially disposed along a sidewall of the trench; and
a fill material disposed in the trench that substantially surrounds the film.

2. The memory device of claim 1, wherein a top portion of the film is substantially at the same level as a top portion of the fill material.

3. The memory device of claim 1, wherein a width of the first conductive layer is smaller than a width of the substrate.

4. The memory device of claim 1 additionally comprising a second dielectric layer disposed along a top portion of the first conductive layer and a second conductive layer disposed on the second dielectric layer.

5. The memory device of claim 4, wherein the second dielectric layer is an oxide/nitride/oxide layer.

6. The memory device of claim 1, wherein a bottom of the film is substantially coplanar with the first dielectric layer.

7. The memory device of claim 1, wherein a cross-section of a top portion of the first conductive layer is substantially rounded in shape.

8. The memory device of claim 1, wherein a thickness of the film is from about 80 Å to about 100 Å.

9. The memory device of claim 1, wherein the first conductive layer is a floating gate layer.

10. The memory device of claim 1, wherein the liner layer comprises a silicon nitride.

11. A semiconductor comprising:
a first conductive layer having a top portion substantially rounded in shape;
a film that covers a bottom portion of the first conductive layer; and
a fill material that substantially surrounds the film.

12. A method of fabricating a memory device comprising:
providing a substrate, a first dielectric layer, and a first conductive layer;
patterning the first dielectric layer and the first conductive layer;
trimming a sidewall of the first conductive layer to form a film;
forming a trench in the substrate;
filling the trench with a fill material;
rounding a top portion of the first conductive layer;
forming a second dielectric layer on the first conductive layer; and
forming a second conductive layer on the second dielectric layer.

13. The method of claim 12, wherein a top portion of the film is at substantially the same level as a top portion of the fill material.

14. The method of claim 12, wherein a width of the first conductive layer is smaller than a width of the substrate.

15. The method of claim 12, wherein the film may be formed by at least one of a plasma oxidation process and a radical oxidation process operating at a temperature in a range of from about 500° C. to about 600° C.

16. The method of claim 12, additionally comprising depositing a sidewall liner substantially along a sidewall of the trench.

17. The method of claim 16, wherein the depositing the sidewall liner comprises a selective nitridation process that forms a silicon nitride substantially along the sidewall but allowing the film to remain substantially free of any silicon nitride.

18. The method of claim 17, wherein the selective nitridation process operates at a pressure in a range of about 1 torr to about 2 torr.

19. The method of claim 17, wherein the selective nitridation process is a plasma nitridation process having a bias in a range of from about 200 W to about 400 W.

20. The method of claim 19, wherein the plasma nitridation process operates at a temperature in a range of from about 400° C. to about 500° C.

21. The method of claim 12, additionally comprising etching back the fill material to provide an exposed portion of the first conductive layer.

22. The method of claim 21, wherein a height of the exposed portion is at least about 200 Å.

23. The method of claim 21, wherein the exposed portion resembles a geometric shape having a top part and a bottom part, the top part narrower than the bottom part.

24. The method of claim 23, wherein the geometric shape is approximately trapezoidal.
